(19) United States
(12) Patent Application Publication
(10) Pub. No.: US 2016/0087601 A1
(43) Pub. Date: Mar. 24, 2016

(54) FULLY ELECTRONICALLY PROGRAMMABLE COMPLEX FILTER

(71) Applicant: KING FAHD UNIVERSITY OF PETROLEUM AND MINERALS, DHAHRAN (SA)

(72) Inventors: HUSSAIN ABDULLAH ALZAHER, DHAHRAN (SA); MOHAMMAD KHALAF ALGHAMDI, DHAHRAN (SA)

(21) Appl. No.: 14/863,399

(22) Filed: Sep. 23, 2015

Related U.S. Application Data
(60) Provisional application No. 62/054,318, filed on Sep. 23, 2014.

(51) Int. Cl. H03H 11/04

(52) U.S. Cl. CPC H03H 11/04

(57) ABSTRACT

The fully electronically programmable complex filter employs a network of current amplifiers (CAs), each CA having differential pairs biased with different tail currents, the outputs being programmed by adjusting these tail currents. Each CA has an RC circuit at its input including a resistor R and a capacitor C, and a feedback path connecting one of its outputs to the RC circuit, thereby offering independent programmability of center frequency, pole frequency, and programmable gain. Optimal gain parameters set the electronically programmable pole frequency, gain and center frequency to accommodate Integrated Services Digital Broadcasting-Terrestrial (ISDB-T) and Terrestrial Digital Multimedia Broadcasting (T-DMB).

### CROSS-REFERENCE TO RELATED APPLICATION

This application claims the benefit of U.S. Provisional Patent Application Ser. No. 62/054,318, filed Sep. 23, 2014.

### BACKGROUND OF THE INVENTION

1. Field of the Invention

The present invention relates to complex filters, and particularly to a fully electronically programmable complex filter applicable for Integrated Services Digital Broadcasting-Terrestrial (ISDB-T) and Terrestrial Digital Multimedia Broadcasting (T-DMB).

2. Description of the Related Art

Mobile digital television is an emerging wireless system as a result of the substantial progress in the digitization of traditional TV. Two of the popular standards are suitable for low IF multi-standard operation, namely, ISDB-T and T-DMB. To date filters applicable to these popular standards have been deficient in that they do not provide independent tuning of the center frequency and bandwidth while maintaining efficient area and power performance.

Thus, a fully electronically programmable complex filter solving the aforementioned problems is desired.

### SUMMARY OF THE INVENTION

The fully electronically programmable complex filter employs a minimum number of current amplifiers. The current amplifiers (CAs) use differential pairs biased with different tail currents, the outputs being programmed by adjusting these tail currents. Each CA has an RC circuit at its input that includes a resistor R and a capacitor C, and a feedback path connecting one of the current amplifier's outputs to the RC circuit The pole frequency, gain, and the center frequency are electronically programmable to accommodate Integrated Services Digital Broadcasting-Terrestrial (ISDB-T) and Terrestrial Digital Multimedia Broadcasting (T-DMB). This configuration avoids the employment of capacitor and/or resistor banks, resulting in a compact design solution while maintaining relatively low power consumption.

These and other features of the present invention will become readily apparent upon further review of the following specification and drawings.

### BRIEF DESCRIPTION OF THE DRAWINGS

FIG. 1 is a block diagram of a fully differential current amplifier.

FIG. 2 is a schematic diagram of a current amplifier with electronically controlled gains for use in a fully electronically programmable complex filter according to the present invention.

FIG. 3 is a schematic diagram of a fully programmable complex filter according to the present invention, being a second-order Chebyshev filter using four current amplifiers of FIG. 2.

FIG. 4 is a block diagram of a typical low IF (intermediate frequency) dual mode ISDB-T and T-DMB receiver of the prior art.

FIG. 5 is a plot showing measured tuning results of an exemplary eighth-order Chebyshev filter (obtained from cascading four sections of the second-order Chebyshev filter shown schematically in FIG. 3) for compliance with the ISDB-T standard using a fully electronically programmable complex filter according to the present invention.

FIG. 6 is a plot showing measured tuning results of an exemplary eighth-order Chebyshev filter for compliance with the T-DMB standard using a fully electronically programmable complex filter according to the present invention.

Similar reference characters denote corresponding features consistently throughout the attached drawings.

### DETAILED DESCRIPTION OF THE PREFERRED EMBODIMENTS

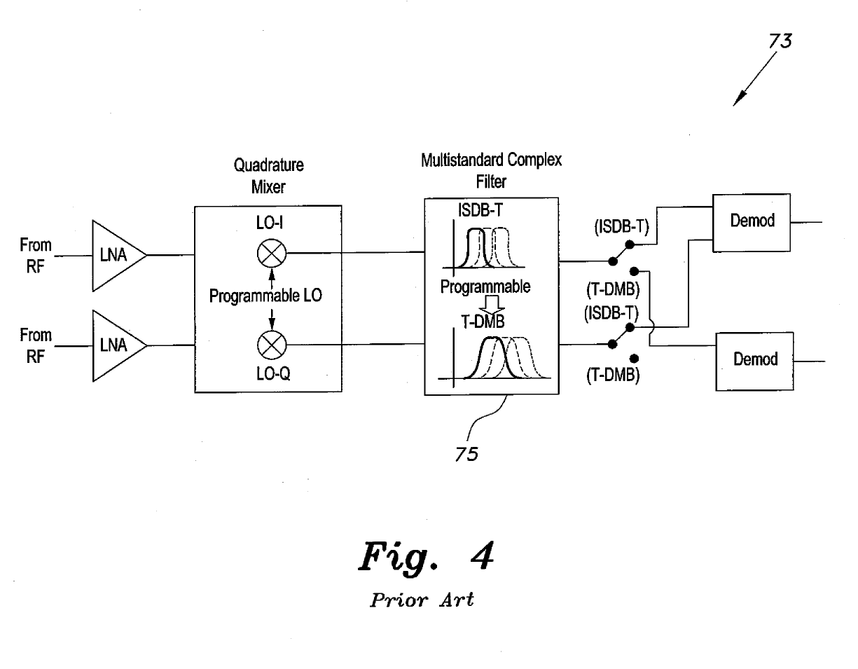

The fully electronically programmable complex filter implements a compact low power complex filter using fully differential current amplifiers 100 (shown in FIG. 1) for dual mode ISDB-T and T-DMB low-IF reception. The typical dual mode receiver 73, shown in FIG. 4, has an unoptimized, non-fully electronically programmable multi-standard complex filter 75. The fully electronically programmable complex filter addresses these problems by providing an optimized, fully electronically programmable complex filter for ISDB-T and T-DMB.

Since ISDB-T and T-DMB standards have different bandwidths, and consequently, preferably different center frequencies, the low-IF complex filter requires tunable center frequency bandwidth for both standards. The present fully electronically programmable complex filter provides gain and develops fully differential filters having a compact layout. A standard 0.18 μm CMOS process is used to produce the circuit for the fully differential filters.

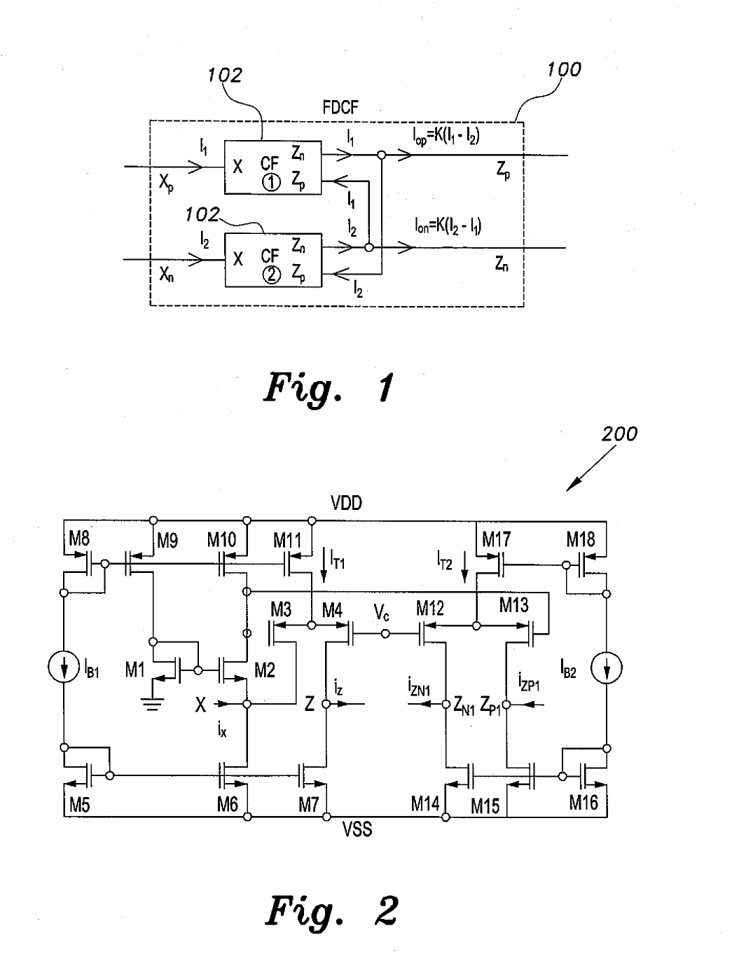

The present fully electronically programmable complex filter is based on current amplifiers (CAs) having the basic CA topology 200, shown in FIG. 2. This CA topology 200 includes a power efficient current amplifier circuit (CA) 200 in which MOS transistors, for example are utilized. In the CA 200, a first set of transistors, including transistors M1 and M2, set the voltage at X terminal to zero, and with the help of negative feedback generated in the CA 200, formed basically by transistor M3, an input resistance in the range of few tens of ohms, such as approximately 50 ohms, is achieved. A current folding output stage including a second set of transistors is used to replace the normal current mirroring output stages, and hence achieve a relatively robust linearity. The input current iₓ, which is forced by the constant (or substantially constant) currents of transistors M2 and M6 to flow into transistor M3, is conveyed to the output port Z by source-coupling transistors M3 with M4 instead of using current mirroring, the second set of transistors forming a first differential pair or set and including the transistors M3 and M4. Since this coupled pair is biased with a constant or substantially constant tail current, the drain current changes in M3-M4 will be equal or substantially equal, but with opposite sign, regardless of their matching resulting in negative type CA with unity gain (i_{z}=iₓ), where an output current i_{z} is equal or substantially equal to the input current iₓ.

A second differential pair or set of transistors, including transistors M12-M13 is connected in parallel with the second set of transistors that includes the transistors M3-M4 to provide two additional current outputs, for example. When the two pairs or sets are biased with different tail currents, it can be shown that the large signal current relationship will be given by:

$${I}_{z P 1} = {I}_{z N 1} = \sqrt{\frac{{I}_{T 2}}{{I}_{T 1}}} \frac{\sqrt{1 - ( \frac{{KV}_{d}^{2}}{4 {I}_{T 2}} )}}{\sqrt{1 - ( \frac{{KV}_{d}^{2}}{4 {I}_{T 1}} )}} {I}_{x} , \qquad ( 1 )$$

where V_{d}=V_{c}−V_{g3} (i.e., the differential voltage of the two source coupled pairs), and K=0.5 μCₒₓW/L where μ is the surface carrier mobility, Cₒₓ is the gate oxide capacitance per unit area, and W and L are the width and length of the channel. Thus, for small signals with Vd<<2[min.(I_{T1},I_{T2})/K]^{1/2}, the relationship simplifies to:

i_{zP1}=i_{zN1}=(I_{T2}/I_{T1})^{1/2}iₓ. (2)

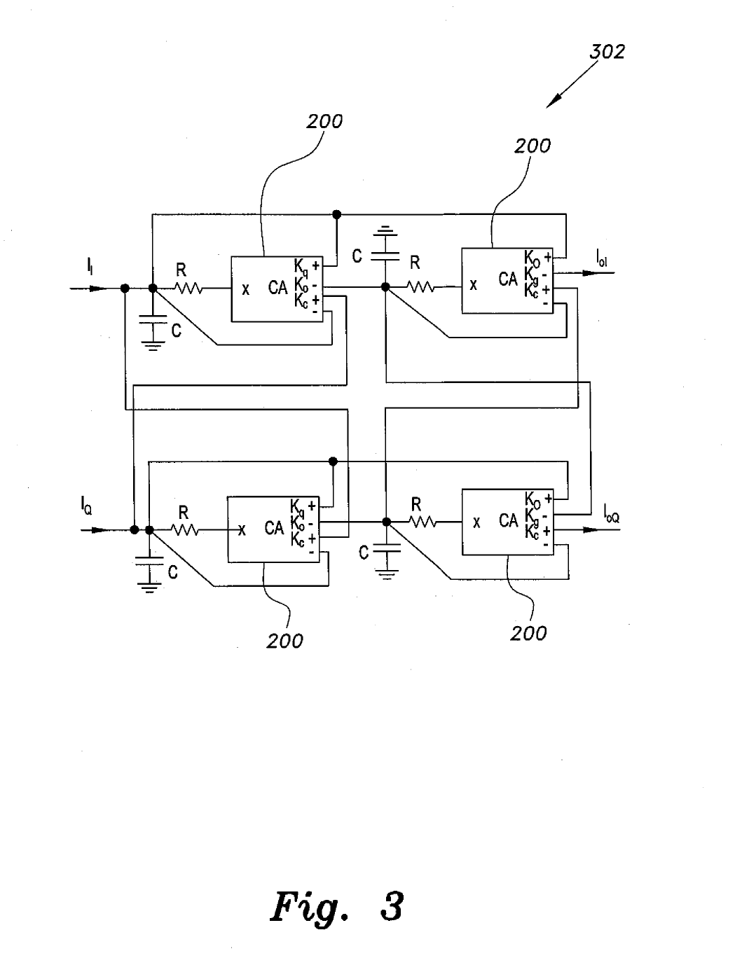

The fully electronically programmable complex filter 302 shown in FIG. 3 is a second-order bandpass poly filter formed by cascading four of the CAs 200, each CA 200 having an RC circuit at its input formed by resistor R and capacitor C and a feedback path connecting one of its outputs to the RC circuit. The two upper CAs of the circuit 102 and the two lower CAs of the circuit 102 form independent two-integrator loops, which, when connected as shown in FIG. 3, provide a fully differential configuration. Such a configuration offers independent programmability of center frequency and pole frequency, and programmable gain. The transfer function is:

$${H}_{p} ( s ) = \frac{{K}_{g} / ( {C}^{2} {R}^{2} )}{{( s - {jK}_{c} / CR )}^{2} + ( s - {jK}_{c} / CR ) {K}_{q} / ( CR ) + {K}_{o}^{2} / ( {C}^{2} {R}^{2} )} . \qquad ( 3 )$$

Therefore, the filter exhibits a polyphase transfer function where the center frequency is ω_{c}=K_{c}/CR, the pole frequency is ωₒ=Kₒ/CR, the pole quality factor is Q₀=1/K_{q}, and the Gain=K_{g}/Kₒ. Clearly, these parameters can be electronically programmed using K_{c}, Kₒ, K_{q}, and K_{g}, respectively. Independent tuning of the bandwidth (2ωₒ) is as important as the center frequency, since both are function of RC products. It would also make the design flexible to accommodate multiple low-IF applications. Providing gain is desirable because it relaxes the gain requirements of the system's amplifiers and also allows optimization of the linearity-noise trade-off of the filter design itself, while avoiding the drawback of capacitor matrices for tuning the center frequency. Thus, the fully electronically programmable complex filter adopts the electronically tunable CA.

The electronically tunable CA 200 of FIG. 2 provides an area-efficient tuning solution while maintaining the low power consumption exhibited by the filter 302 of FIG. 3. It can be shown that the outputs of the current amplifier can be approximated as:

i_{z}=iₓ

i_{zP1}=i_{zN1}≈(I_{T2}/I_{T1})^{1/2}iₓ, (4)

where iₓ is the input current and i_{z} is the output current, I_{zP1} being a positive current mirror output and i_{zN1} being a negative current mirror output. Thus, the outputs i_{zP1} and i_{zN1} would exhibit electronically controlled gains, which can be programmed by adjusting the tail currents, I_{T1} and I_{T2} related to the current source producing i_{z} and its mirror outputs producing i_{zP1} and i_{zN1}, respectively. Note that the output current i_{z} equals the input current iₓ, and the unity gain output is also important, as it is needed to realize the unity feedback factors shown in FIG. 3. Extra output currents with different gains can be obtained by adding more output stages, each stage providing both positive and negative signals.

A fully differential CA (FDCA) is a four terminal device with two input currents (I₁ and I₂) and two output currents (Iₒ₁ and Iₒ₂). A possible realization of a fully differential complex filter (FDCF) 100 is depicted in FIG. 1. It employs two dual-output CAs 102 having gain K, where subtractions are performed at the output terminals.

Assuming perfect current transfer, it is observed that the differential gain is 2K while the common-mode output is zero. The non-ideal performance of this circuit can be explored by assuming current transfer of Kₚ and Kₙ for the positive and negative outputs of the CAs 102, respectively. It can be shown that the differential-mode and common-mode gains are given by:

A_{diff}=(Kₙ₁+Kₙ₂+K₁+Kₚ₂)/2, (5)

A_{cm}=(Kₙ₁−Kₙ₂)+(Kₚ₁−Kₚ₂). (6)

It is clear that this topology has the advantage that A_{cm} depends on matching between two identical CAs.

An eighth-order filter is formed through cascading four sections of the filter shown in FIG. 3. The eighth-order filter is designed for different center frequencies and bandwidth requirements. It is obtained by cascading the four sections of filter 302, as shown in FIG. 3. The passive components of R=32 kΩ and C=10 pF are selected. The required gain settings of various amplifiers are calculated as per Table 1, given below, detailing a gain setting example of the CAs for ISDB-T and T-DMB. Simulation results reveal that the filter prototype achieves the desired frequency characteristics. But it is observed that the gain settings of Table 1 suffer from a wide spread of gains/attenuations. It can be seen from Table 1 that the minimum gain is 0.04, whereas the maximum gain is 3.39. The condition V_{d}<<2[min.(I_{T1},I_{T2})/K]^{1/2} is required for linear operation of the CA. Also, it can be observed that the minimum biasing current is attained when the maximum gain and attenuation are equal. It can be shown this is achieved when they are multiplied by 2.68. This would increase K_{q4} (ISDB-T) to approximately 0.11 and K_{c} (T-DMB with BW=18/16) to 9.10. Therefore, the maximum need current ratios I_{T1}/I_{T2} and I_{T2}/I_{T1} would be 9.10 instead of 1/0.04=25 for the design values of Table 1. This increased gain must be accompanied by an increase in the value of passive components to maintain the same filter's selectivity requirements. In order to maintain an acceptable area, increasing the capacitor values is avoided, while the resistors are increased to 86 kΩ.

TABLE 1
Initial gain settings of the CAs

| | | | Kₒ₁ | Kₒ₂ | Kₒ₃ | Kₒ₄ | | | | |
|---|---|---|---|---|---|---|---|---|---|---|
| Standard | f_{c} | K_{c} | K_{g1} | K_{g2} | K_{g3} | K_{g4} | K_{q1} | K_{q2} | K_{q3} | K_{q4} |
| ISDB-T | BW*12/16 | 0.75 | 0.13 | 0.26 | 0.37 | 0.44 | 0.19 | 0.16 | 0.11 | 0.04 |
| | | | 0.26 | 0.52 | 0.74 | 0.88 | | | | |
| | BW*15/16 | 0.94 | 0.13 | 0.26 | 0.37 | 0.44 | 0.19 | 0.16 | 0.11 | 0.04 |
| | | | 0.26 | 0.52 | 0.74 | 0.88 | | | | |
| | BW*18/16 | 1.13 | 0.13 | 0.26 | 0.37 | 0.44 | 0.19 | 0.16 | 0,11 | 0.04 |
| | | | 0.26 | 0.52 | 0.74 | 0.88 | | | | |
| T-DMB | BW*12/16 | 2.26 | 0.45 | 0.90 | 1.30 | 1.52 | 0.66 | 0.56 | 0.38 | 0.13 |
| | | | 0.90 | 1.80 | 2.60 | 3.04 | | | | |
| | BW*15/16 | 2.83 | 0.45 | 0.90 | 1.30 | 1.52 | 0.66 | 0.56 | 0.38 | 0.13 |
| | | | 0.90 | 1.80 | 2.60 | 3.04 | | | | |
| | BW*18/16 | 3.39 | 0.45 | 0.90 | 1.30 | 1.52 | 0.66 | 0.56 | 0.38 | 0.13 |
| | | | 0.90 | 1.80 | 2.60 | 3.04 | | | | |

In addition, the performance of the filter is further improved by proper distribution of the gain over the various stages. With equal gain of 2 for each stage K_{g1}, K_{g2}, K_{g3}, and K_{g4}, the output would be 0.70, 1.40, 2.00, and 2.36 for ISDB-T, while the output would be 2.40, 4.80, 6.97, and 8.15 for T-DMB, respectively. However, minimizing the ratios of I_{T1}/I_{T2} and I_{T2}/I_{T1} is achieved with equal K_{g} of 1.47 for ISDB-T and 5.05 for T-DMB. Therefore, the respective gains of the four stages would be 4.2, 2.1, 1.47, and 1.25 for ISDB-T and 4.21, 2.11, 1.45, and 1.25 for T-DMB. The optimized new gain settings are given in Table 2.

TABLE 2
Optimized gain settings of the CAs

| | | | Kₒ₁ | Kₒ₂ | Kₒ₃ | Kₒ₄ | | | | |
|---|---|---|---|---|---|---|---|---|---|---|
| Standard | f_{c} | K_{c} | K_{g1} | K_{g2} | K_{g3} | K_{g4} | K_{q1} | K_{q2} | K_{q3} | K_{q4} |
| ISDB-T | BW*12/16 | 2.01 | 0.35 | 0.70 | 1.00 | 1.18 | 0.51 | 0.43 | 0.30 | 0.11 |
| | | | 1.47 | 1.47 | 1.47 | 1.47 | | | | |
| | BW*5/16 | 2.52 | 0.35 | 0.70 | 1.00 | 1.18 | 0.51 | 0.43 | 0.30 | 0.11 |
| | | | 1.47 | 1.47 | 1.47 | 1.47 | | | | |
| | BW*18/16 | 3.03 | 0.35 | 0.70 | 1.00 | 1.18 | 0.51 | 0.43 | 0.30 | 0.11 |
| | | | 1.47 | 1.47 | 1.47 | 1.47 | | | | |
| T-DMB | BW*12/16 | 6.06 | 1.20 | 2.40 | 3.48 | 4.07 | 1.77 | 1.50 | 1.02 | 0.35 |
| | | | 5.05 | 5.05 | 5.05 | 5.05 | | | | |
| | BW*15/16 | 7.58 | 1.20 | 2.40 | 3.48 | 4.07 | 1.77 | 1.50 | 1.02 | 0.35 |
| | | | 5.05 | 5.05 | 5.05 | 5.05 | | | | |
| | BW*18/16 | 9.10 | 1.20 | 2.40 | 3.48 | 4.07 | 1.77 | 1.50 | 1.02 | 0.35 |
| | | | 5.05 | 5.05 | 5.05 | 5.05 | | | | |

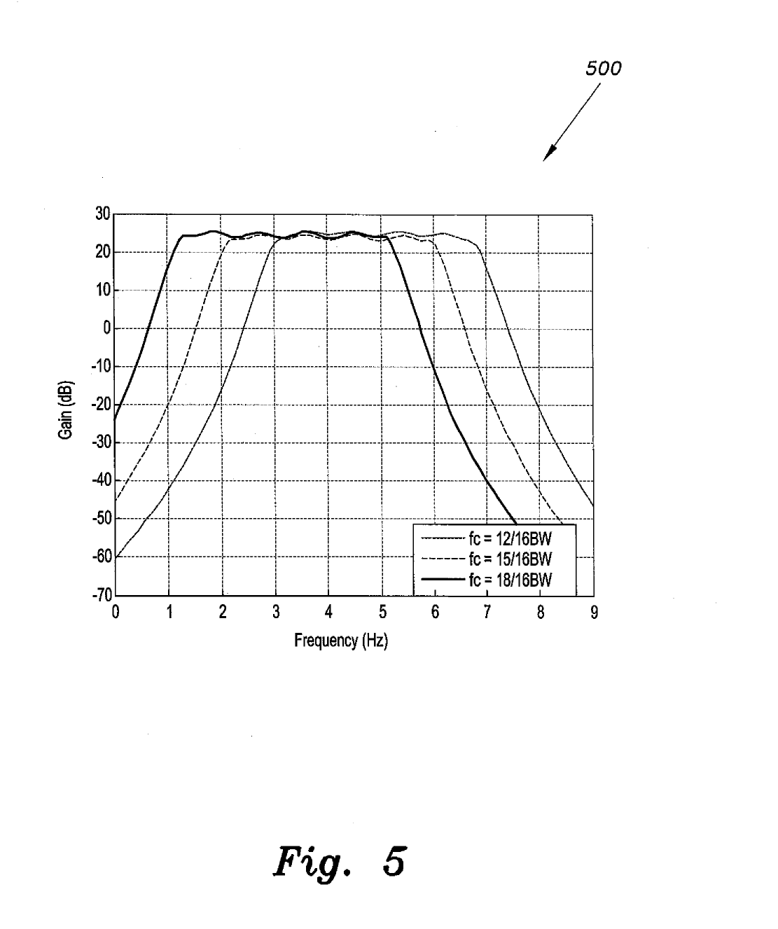

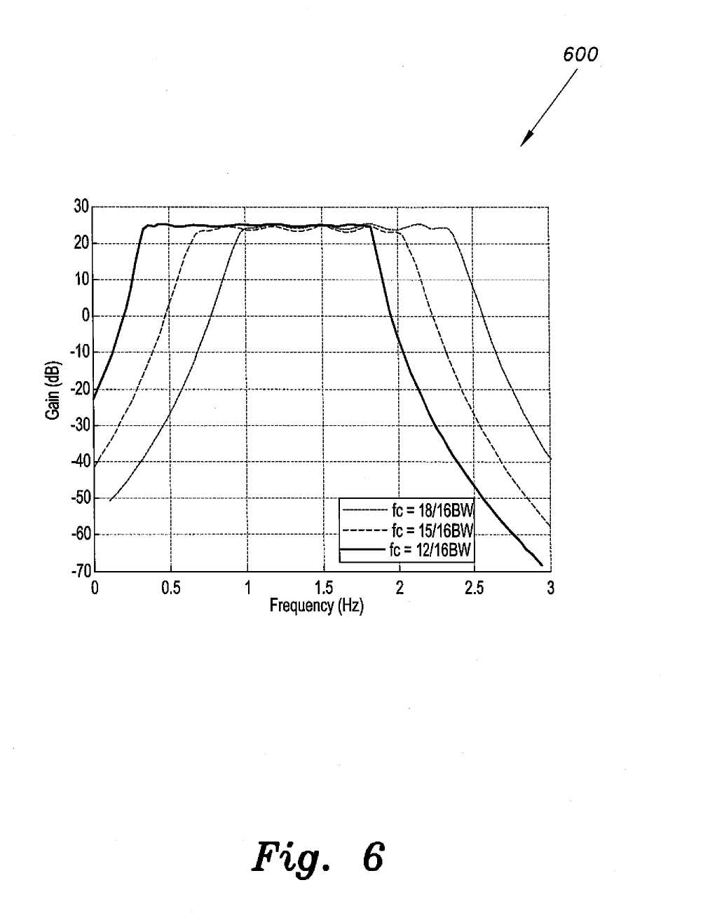

The eighth-order filter was fabricated in 0.18 μm CMOS. The supply voltages were set to ±0.9V, and the typical total filter current of 2.84 mA is used. Measured results showing required center frequency tuning without disturbing the bandwidth for ISDB-T and T-DMB are shown in plot 500 of FIG. 5 and plot 600 of FIG. 6, respectively. A summary of the performance results is shown in Table 3.

TABLE 3
Performance results of present complex filter

| | | |
|---|---|---|
| Characteristics | Related Art | This work |

| | | | |
|---|---|---|---|
| Applications | ISDB-T | ISDB-T | T-DMB |

| Process | SiGe BiCMOS | 0.18 μm |
|---|---|---|
| | | CMOS |
| Order | 7 | 8 |

| | | | |
|---|---|---|---|
| f_{c} (MHz) | 0.5 | 0.4 | 1.5 |

| | | |
|---|---|---|
| Supply (V) | 2.9 | 1.8 |
| Power (mW) | 20.3 mW | 5.1 mW |

| | | | |
|---|---|---|---|
| Linearity (dBm) | — | 16 | 18 |
| Total input noise (μV) | 7.2 | 11 | 23 |
| SFDR (dB) | — | 68.3 | 65.2 |
| IRR (dB) | 37 | 38 | 41 |

| | | |
|---|---|---|
| Area (mm²) | 6 | 0.51 |

Design of a versatile complex filter with fully programmable characteristics is presented. The filter can be electronically configured to realize responses with different center frequency, bandwidth and gain. It also avoids the use of capacitor and/or resistor banks, leading to a more area-efficient design solution. An eighth-order filter is implemented in 0.18 μm standard CMOS ICs in an area of 0.51 mm². Experimental results show that the filter fulfills the selectivity requirements of ISDB-T. The present filter exhibits programmable characteristics that are used to modify the filter response to accommodate the T-DMB standard. The filter achieves SFDR of 68.3 dB for ISDB-T and 65.2 dB for T-DMB with total power consumption of 5.1 mW. Four stages of the fully electronically programmable complex filter 302 can be connected in a series cascade to form the eighth-order filter, which can then be substituted for the filter 75 in the ISDB-T/T-DMB receiver 73 (of FIG. 4) so that the differential inputs of the first stage are connected to local oscillator in-phase (LO-I) and local oscillator quadrature (LO-Q) outputs of the quadrature mixer. A switch then switches the differential outputs of the fourth stage to the appropriate demodulator (either the ISDB-T demodulator or the T-DMB demodulator).

It is to be understood that the present invention is not limited to the embodiments described above, but encompasses any and all embodiments within the scope of the following claims.

We claim:

1. A fully electronically programmable complex filter, comprising:
a first network of current amplifiers (CAs), each of the current amplifiers respectively having an RC circuit connected to its input and a feedback path connecting a respective output to the RC circuit, the first network of current amplifiers forming a first filter having a transfer function characterized by the relation,
$${H}_{p} ( s ) = \frac{{K}_{g} / ( {C}^{2} {R}^{2} )}{{( s - j {K}_{c} / CR )}^{2} + ( s - j {K}_{c} / CR ) {K}_{q} / ( CR ) + {K}_{o}^{2} / ( {C}^{2} {R}^{2} )} ,$$
wherein ω_{c}=K_{c}/CR is the center frequency, ωₒ=Kₒ/CR is the pole frequency, Q₀=1/K_{q} is the pole quality factor, and Kg/Ko is the gain of the filter, and
wherein each current amplifier has differential outputs characterized by the relations,
i_{z}=iₓ
i_{zP1}=i_{zN1}≈(I_{T2}/I_{T1})^{1/2}iₓ,
where iₓ is input current and i_{z} is a current source output, i_{zP1} being a positive current mirror output, and i_{zN1} being a negative current mirror output, thereby providing electronic programmability of the center frequency, pole frequency, quality, and CA gains, K_{c}, Kₒ, K_{q} and K_{g} via adjustment of the current source and current mirror tail currents, I_{T1}, and I_{T2}, respectively.

2. The fully electronically programmable complex filter according to claim 1, further comprising a second network of current amplifiers, each of the current amplifiers respectively having an RC circuit connected to its input and a feedback path connecting a respective output to the RC circuit, the second network of current amplifiers forming a second filter having the same transfer function Hₚ(s), the second and first filters being connected to each other to provide a fully differential first channel bandwidth complex filter and a fully differential second channel bandwidth complex filter.

3. The fully electronically programmable complex filter according to claim 2, further comprising four sections of the fully differential filters connected together to form an eighth-order filter tunable as a channel-select filter operable between ISDB-T as the first channel bandwidth and T-DMB as the second channel bandwidth.

4. The fully electronically programmable complex filter according to claim 3, wherein the first channel bandwidth for ISDB-T further comprises:
a first center frequency gain K_{c}≅2.01, thereby setting the center frequency f_{c} to bandwidth (BW)*12/16;
a second center frequency gain K_{c}≅2.52, thereby setting the center frequency f_{c} to BW*15/16;
a third center frequency gain K_{c}≅3.03, thereby setting the center frequency f_{c} to BW*18/16;
a first pole frequency gain setting Kₒ₁≅0.35 the first pole frequency gain setting being associated with a first CA stage of the first channel bandwidth;
a first CA gain setting K_{g1}≅1.47, the first CA gain setting being associated with the first CA stage of the first channel bandwidth;
a first quality gain setting K_{q1}≅0.51 the first quality gain setting being associated with the first CA stage of the first channel bandwidth;
a second pole frequency gain setting Kₒ₂≅0.70 second pole frequency gain setting being associated with a second CA stage of the first channel bandwidth;
a second CA gain setting K_{g2}≅1.47, the second CA gain setting being associated with the second CA stage of the first channel bandwidth;
a second quality gain setting K_{q2}≅0.43 the second quality gain setting being associated with the second CA stage of the first channel bandwidth;
a third pole frequency gain setting Kₒ₃≅1.00 the third pole frequency gain setting being associated with a third CA stage of the first channel bandwidth;
a third CA gain setting K_{g3}≅1.47, the third CA gain setting being associated with the third CA stage of the first channel bandwidth;
a third quality gain setting K_{q3}≅0.30 the third quality gain setting being associated with the third CA stage of the first channel bandwidth;
a fourth pole frequency gain setting Kₒ₄≅1.18, the fourth pole frequency gain setting being associated with a fourth CA stage of the first channel bandwidth;
a fourth CA gain setting K_{g4}≅1.47, the fourth CA gain setting being associated with the fourth CA stage of the first channel bandwidth; and
a fourth quality gain setting K_{q4}≅0.11 the fourth quality gain setting being associated with the fourth CA stage of the first channel bandwidth.

5. The fully electronically programmable complex filter according to claim 4, wherein the second channel bandwidth for T-DMB further comprises:
a first center frequency gain K_{c}≅6.06, thereby setting the center frequency f_{c} to BW*12/16;
a second center frequency gain K_{c}≅7.58, thereby setting the center frequency f_{c} to BW*15/16;
a third center frequency gain K_{c}≅9.10, thereby setting the center frequency f_{c} to BW*18/16;
a first pole frequency gain setting Kₒ₁≅1.20 the first pole frequency gain setting being associated with a first CA stage of the second channel bandwidth;
a first CA gain setting K_{g1}≅5.05, the first CA gain setting being associated with the first CA stage of the second channel bandwidth;
a first quality gain setting K_{q1}≅1.77 the first quality gain setting being associated with the first CA stage of the second channel bandwidth;
a second pole frequency gain setting Kₒ₂≅2.40 the second pole frequency gain setting being associated with a second CA stage of the second channel bandwidth;
a second CA gain setting K_{g2}≅5.05, the second CA gain setting being associated with the second CA stage of the second channel bandwidth;
a second quality gain setting K_{q2}≅1.50 the second quality gain setting being associated with the second CA stage of the second channel bandwidth;
a third pole frequency gain setting Kₒ₃≅3.48 the third pole frequency gain setting being associated with a third CA stage of the second channel bandwidth;
a third CA gain setting K_{g3}≅5.05, the third CA gain setting being associated with the third CA stage of the second channel bandwidth;
a third quality gain setting K_{q3}≅1.02 the third quality gain setting being associated with the third CA stage of the second channel bandwidth;
a fourth pole frequency gain setting Kₒ₄≅4.07, the fourth pole frequency gain setting being associated with a fourth CA stage of the second channel bandwidth;
a fourth CA gain setting K_{g4}≅5.05, the fourth CA gain setting being associated with the fourth CA stage of the second channel bandwidth; and
a fourth quality gain setting K_{q4}≅0.35 the fourth quality gain setting being associated with the fourth CA stage of the second channel bandwidth.

6. The fully electronically programmable complex filter according to claim 5, further comprising:
in an ISDB-T/T-DMB band selectable receiver, a quadrature mixer having a local oscillator in phase output (LO-I) and a local oscillator quadrature output (LO-Q);
a first differential input of the fully electronically programmable complex filter connected to the (LO-I) quadrature mixer output;
a second differential input of the fully electronically programmable complex filter connected to the (LO-Q) quadrature mixer output;
a first demodulator adapted for processing of ISDB-T signals;
a second demodulator adapted for processing of T-DMB signals; and
a switch selectively connecting the differential outputs of the fully electronically programmable complex filter to one of the first and second demodulators.

7. The fully electronically programmable complex filter according to claim 3, wherein the second cascade is operable as the second channel bandwidth for T-DMB further comprising:
a first center frequency gain K_{c}≅6.06, thereby setting the center frequency f_{c} to BW*12/16;
a second center frequency gain K_{c}≅7.58, thereby setting the center frequency f_{c} to BW*15/16;
a third center frequency gain K_{c}≅9.10, thereby setting the center frequency f_{c} to BW*18/16;
a first pole frequency gain setting Kₒ₁≅1.20 said first pole frequency gain setting being associated with a first CA stage of the second cascade;
a first CA gain setting K_{g1}≅5.05, said first CA gain setting being associated with the first CA stage of the second cascade;
a first quality gain setting K_{q1}≅1.77 said first quality gain setting being associated with the first CA stage of the second cascade;
a second pole frequency gain setting Kₒ₂≅2.40 said second pole frequency gain setting being associated with a second CA stage of the second cascade;
a second CA gain setting K_{g2}≅5.05, said second CA gain setting being associated with the second CA stage of the second cascade;
a second quality gain setting K_{q2}≅1.50 said second quality gain setting being associated with the second CA stage of the second cascade;
a third pole frequency gain setting Kₒ₃≅3.48 said third pole frequency gain setting being associated with a third CA stage of the second cascade;
a third CA gain setting K_{g3}≅5.05, said third CA gain setting being associated with the third CA stage of the second cascade;
a third quality gain setting K_{q3}≅1.02 said third quality gain setting being associated with the third CA stage of the second cascade;
a fourth pole frequency gain setting Kₒ₄≅4.07, said fourth pole frequency gain setting being associated with a fourth CA stage of the second cascade;
a fourth CA gain setting K_{g4}≅5.05, said fourth CA gain setting being associated with the fourth CA stage of the second cascade; and
a fourth quality gain setting K_{q4}≅0.35 said fourth quality gain setting being associated with the fourth CA stage of the second cascade.

8. A polyphase channel-select filter, comprising a plurality of filter sections, each of the sections including four current amplifiers configured as fully differential current amplifiers having cross-coupled in-phase and quadrature paths to form a second-order filter section having a plurality of inputs and a plurality of outputs, the outputs including independently programmable center frequency, gain, and pole.

9. The polyphase channel-select filter according to claim 8, wherein four of the second-order filter sections are connected in cascade to form an eighth-order filter tunable between ISDB-T and T-DMB channel bandwidths.

10. The polyphase channel-select filter according to claim 8, wherein each of said four current amplifiers satisfies the transfer function:
$${H}_{p} ( s ) = \frac{{K}_{g} / ( {C}^{2} {R}^{2} )}{{( s - {jK}_{C} / CR )}^{2} + ( s - {jK}_{C} / CR ) {K}_{q} / ( CR ) + {K}_{o}^{2} / ( {C}^{2} {R}^{2} )} .$$
where the center frequency is ω_{c}=K_{c}/CR, the pole frequency is ωₒ=Kₒ/CR, the pole quality factor is Qₒ=1/K_{q}, the Gain=K_{g}/Kₒ, and C and R are the values of resistance and capacitance in an RC filter at the inputs of the current amplifiers.

11. The polyphase channel-select filter according to claim 10, wherein the filter section has a bandwidth defined by 2ωₒ.

12. The polyphase channel-select filter according to claim 8, wherein said four current amplifiers comprise circuits having differential pairs of CMOS transistors defining tail currents, the filter sections having a user-selectable center frequency and bandwidth by adjusting the tail currents to program gains of said four current amplifiers.
